(19) United States
(12) Patent Application Publication
(10) Pub. No.: US 2024/0186296 A1
(43) Pub. Date: Jun. 6, 2024

(54) SEMICONDUCTOR DEVICE

(71) Applicant: Kioxia Corporation, Tokyo (JP)

(72) Inventors: Akio WATANABE, Sagamihara (JP); Yusuke AKADA, Yokohama (JP); Hideko MUKAIDA, Taito (JP)

(73) Assignee: Kioxia Corporation, Tokyo (JP)

(21) Appl. No.: 18/519,786

(22) Filed: Nov. 27, 2023

(30) Foreign Application Priority Data
Dec. 6, 2022 (JP) 2022-194978

(51) Int. Cl. H01L 25/065

(52) U.S. Cl. CPC H01L 25/0657; H01L 24/16; H01L 2224/16225; H01L 2225/06562

(57) ABSTRACT

A semiconductor device according to the present embodiment includes a substrate having a first surface, a first spacer and a second spacer, a first semiconductor chip, and a stacked body. The first semiconductor chip is provided on the first surface so as to be disposed between the first spacer and the second spacer. The stacked body is a stacked body that is provided above the first spacer, the second spacer, and the first semiconductor chip and in which a plurality of second semiconductor chips are stacked in a first direction. One of the second semiconductor chips, which is provided on the lowermost second semiconductor chip, is stacked with an offset relative to the lowermost second semiconductor chip in a second direction. A central position of the first semiconductor chip is separated from a central position of the lowermost second semiconductor chip in the second direction.

### CROSS REFERENCE TO RELATED APPLICATIONS

This application is based upon and claims the benefit of priority from the prior Japanese Patent Application No. 2022-194978, filed on Dec. 6, 2022, the entire contents of which are incorporated herein by reference.

### FIELD

The embodiments of the present invention relate to a semiconductor device.

### BACKGROUND

In a semiconductor package structure, for example, a plurality of memory chips are stacked on a controller chip in some cases. The plurality of memory chips are stacked with misalignment (offset) to expose metal pads for connection to a bonding wire in some cases. With increase in the sum of offset amounts along with increase in the number of stacked tiers, cracks are potentially generated at positions where stress is high at memory chip mounting (die bonding).

### BRIEF DESCRIPTION OF THE DRAWINGS

FIG. 1A is a diagram illustrating an example of the configuration of a semiconductor device according to a first embodiment;

FIG. 1B is a diagram illustrating the example of the configuration of the semiconductor device according to the first embodiment;

FIG. 1C is a diagram illustrating the example of the configuration of the semiconductor device according to the first embodiment;

FIG. 2 is a cross sectional view illustrating the example of the configuration of the semiconductor device according to the first embodiment;

FIG. 3 is a cross sectional view illustrating an example of the relation between the position of a semiconductor chip and the stress at mounting of the semiconductor chip, according to the first embodiment;

FIG. 4 is a cross sectional view illustrating an example of the relation between the position of a semiconductor chip and the stress at mounting of the semiconductor chip, according to a first comparative example;

FIG. 5 is a cross sectional view illustrating an example of the configuration of a semiconductor device according to a second embodiment;

FIG. 6 is a cross sectional view illustrating an example of the configuration of a semiconductor device according to a third embodiment;

FIG. 7 is a cross sectional view illustrating an example of the configuration of a semiconductor device according to a fourth embodiment; and

FIG. 8 is a plan view illustrating an example of the configuration of a semiconductor device according to a fifth embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a substrate having a first surface, a first spacer and a second spacer, a first semiconductor chip, and a stacked body. The first spacer and the second spacer are provided at different positions on the first surface. The first semiconductor chip is provided on the first surface so as to be disposed between the first spacer and the second spacer. The stacked body is a stacked body that is provided above the first spacer, the second spacer, and the first semiconductor chip and in which a plurality of second semiconductor chips are stacked in a first direction substantially perpendicular to the first surface. One of the second semiconductor chips, which is provided on the lowermost second semiconductor chip, is stacked with an offset relative to the lowermost second semiconductor chip in a second direction substantially parallel to the first surface. A central position of the first semiconductor chip is separated from a central position of the lowermost second semiconductor chip in the second direction when viewed in the first direction.

### First Embodiment

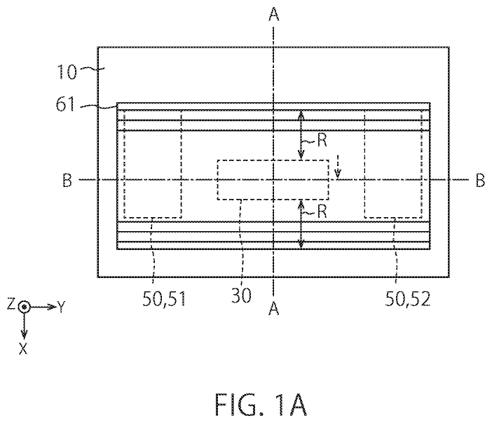

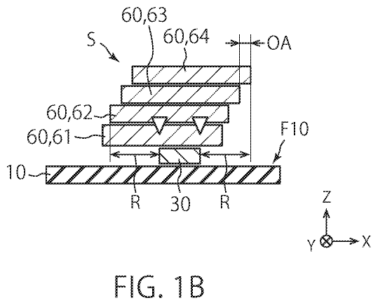

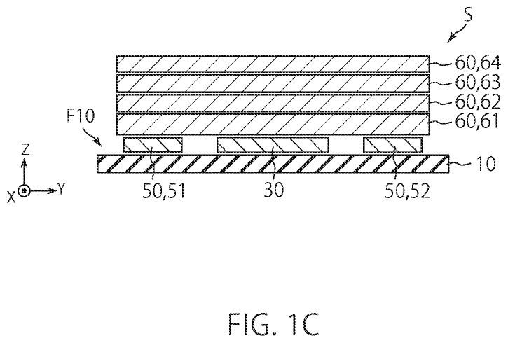

FIGS. 1A, 1B, and 1C are diagrams illustrating an exemplary configuration of a semiconductor device 1 according to a first embodiment. Line A-A in a plan view of FIG. 1A indicates a section corresponding to a cross sectional view of FIG. 1B. Line B-B in the plan view of FIG. 1A indicates a section corresponding to a cross sectional view of FIG. 1C.

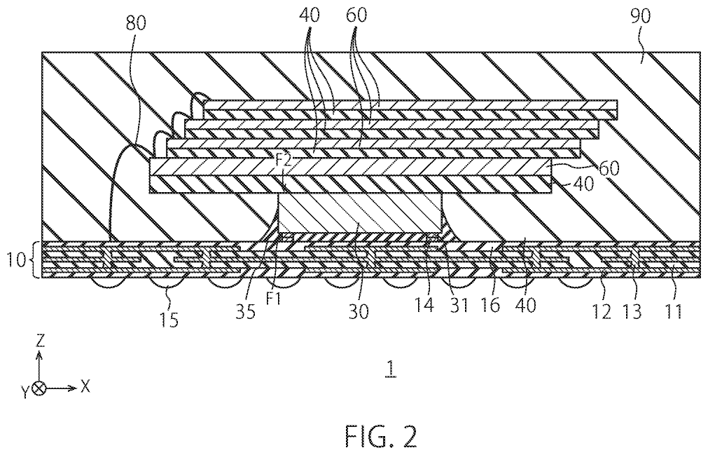

FIG. 2 is a cross sectional view illustrating an example of the configuration of the semiconductor device 1 according to the first embodiment. FIG. 2 is a cross sectional view of the section along line A-A in the plan view of FIG. 1A, illustrating FIG. 1B in more detail.

FIGS. 1A, 1B, 1C, and 2 illustrate an X direction and a Y direction parallel to a front surface of a wiring substrate 10 and perpendicular to each other, and a Z direction perpendicular to the front surface of the wiring substrate 10. In the present specification, the positive Z direction is treated as an upward direction, and the negative Z direction is treated as a downward direction. The negative Z direction may be or may not be aligned with the direction of gravity.

The semiconductor device 1 according to the present embodiment is, for example, a NAND flash memory. The semiconductor device 1 includes the wiring substrate 10, a semiconductor chip 30, a resin layer 35, a resin layer 90, a resin layer 40, a spacer 50, a semiconductor chip 60, and a bonding wire 80. The resin layer 90 is what is called mold resin and is sealing resin. The present embodiment is not limited to a NAND flash memory. A plurality of stacked semiconductor chips 60 are referred to as a stacked body S. The resin layers 35, 40, and 90 and the bonding wire 80 are omitted in FIGS. 1A, 1B, and 1C but illustrated in FIG. 2.

As illustrated in FIG. 2, the wiring substrate 10 includes an insulation substrate 11, wires 12, contact plugs 13, metal pads 14, solder balls 15, and a solder resist 16. The insulation substrate 11 is, for example, prepreg and is made of a composite material of fiber reinforcement materials such as glass fiber, and thermosetting resin such as epoxy. The insulation substrate 11 may be made of an insulation material such as glass epoxy resin or ceramic (alumina-based or AlN-based). Each wire 12 is provided on a front or back surface of the insulation substrate 11 or inside the insulation substrate 11 and electrically connects a metal pad 14 and a solder ball 15. Each metal pad 14 may be part of a wire 12. The contact plugs 13 are provided to penetrate inside the insulation substrate 11 and electrically connect the wires 12. Each metal pad 14 is connected to a metal bump 31 of the semiconductor chip 30 on the front surface of the wiring substrate 10. Each solder ball 15 is connected to the corresponding wire 12 on a back surface of the wiring substrate 10. The wires 12, the contact plugs 13, and the metal pads 14 are each a single material film, a composite film, or an alloy film of conductive materials such as Cu, Ni, Au, Sn, Ag, Bi, and Pd. The solder balls 15 are each, for example, a single material film, a composite film, or an alloy film of a conductive material such as Sn, Ag, Cu, Au, Bi, Zn, In, Sb, and Ni. The solder resist 16 is provided on the front and back surfaces of the wiring substrate 10 between adjacent metal pads 14, around a metal pad 14, or between adjacent solder balls 15 and electrically insulates them. The solder resist 16 may cover the surface of each wire 12 and protect the wire 12.

The semiconductor chip 30 is, for example, a controller chip configured to control a memory chip. The semiconductor chip 30 has a surface F1 facing the wiring substrate 10, and a surface F2 opposite the surface F1. The plurality of metal bumps 31 are provided on the surface F1. The metal bumps 31 are connected (welded) to the metal pads 14 of the wiring substrate 10. In other words, the semiconductor chip 30 is flip-chip connected on the wiring substrate 10. The metal bumps 31 are made of conductive metal such as solder. A substrate for the semiconductor chip may be, for example, a silicon substrate, a GaAg substrate, or a SiC substrate.

The resin layer 35 fills a gap between the wiring substrate 10 and the surface F1 of the semiconductor chip 30. The resin layer 35 is, for example, underfill and made of a liquid non-conductive resin material. The resin layer 35 covers around the metal pads 14 and the metal bumps 31. Accordingly, the resin layer 35 supports connection between the metal pads 14 and the metal bumps 31 and prevents disconnection between the metal pads 14 and the metal bumps 31.

The resin layer 35 may be made of, for example, epoxy resin, silicone resin, epoxy/silicone mixed resin, acrylic resin, polyimide resin, polyamide resin, or phenol resin as a base material.

The resin layer 35 contains, as an additive material, a reductive material such as alcohol or organic acid for removing a metal oxide film formed on the surface of each metal bump 31. The alcohol is at least one kind selected from among methanol, ethanol, isopropyl alcohol, polyvinyl alcohol, ethylene glycol, propylene glycol, diethylen glycol, glycerin, triethylene glycol, tetraethylene glycol, carbitol, cellosolve alcohol, and the like. Alternatively, the alcohol may be an alkyl ether material. The material is, for example, diethylen glycol monobutyl ether or triethylene glycol dimethyl ether. Alternatively, the material may be alkane, amine compound, or the like. The material is, for example, formamide or dimethyl formamide. These materials may be used alone or may be used as a mixture of a plurality of materials. Organic acid may be added to these materials. Examples of the organic acid include formic acid, acetic acid, benzoic acid, abietic acid, palstric acid, dehydroabietic acid, iso-pimaric acid, neoabietic acid, pimaric acid, and rosin. These materials may be used alone or may be used as a mixture of a plurality of materials. The resin layer 35 is applied by a method such as a dispense method (jet method or screw method) or a printing method. The resin layer 35 has a function to remove an oxide film (SnO or SnO₂) or the like on the surfaces of the metal bumps 31 and the metal pads 14 through reduction.

As illustrated in FIGS. 1A, 1B, and 1C, the spacer 50 is provided around the semiconductor chip 30 on the wiring substrate 10 with the resin layer 40 (not illustrated) interposed therebetween. The resin layer 40 is, for example, a die attach film (DAF). The spacer 50 is bonded on the wiring substrate 10 by the resin layer 40. The spacer 50 has a height substantially equal to the height of the surface F2 of the semiconductor chip 30 and supports the semiconductor chips 60. The spacer 50 is provided, for example, on each side of the semiconductor chip 30 on the front surface of the wiring substrate 10. The spacer 50 is made of a material such as silicon, glass, ceramic, an insulation substrate, or a metal plate. For improvement of adhesiveness, an organic film made of polyimide resin, polyamide resin, epoxy resin, acrylic resin, phenol resin, silicone resin, polybenzoxazole (PBO) resin, or the like may be formed on the spacer 50.

Each semiconductor chip 60 is, for example, a memory chip including a NAND flash memory. The semiconductor chip 60 is provided above the semiconductor chip 30 and fixed on the semiconductor chip 30 and the spacer 50 by the resin layer 40. The semiconductor chip 60 includes, for example, a stereoscopic memory cell array in which a plurality of memory cells are three-dimensionally disposed. The resin layer 40 is provided on the surface F2 of the semiconductor chip 30 and the spacer 50 and fixes the semiconductor chip 60 on the semiconductor chip 30 and the spacer 50.

As illustrated in FIG. 2, the bonding wire 80 electrically connects a metal pad of each semiconductor chip 60 and a metal pad of the wiring substrate 10. The resin layer 90 covers and protects the entire structure on the wiring substrate 10, such as the semiconductor chip 30, the semiconductor chips 60, and the bonding wire 80. The semiconductor chips 60 are stacked with offsets to expose the metal pads for connection to the bonding wire 80.

Disposition of each component of the semiconductor device 1 will be described below in detail with reference to FIGS. 1A, 1B, and 1C.

The wiring substrate 10 has a surface F10.

The spacer 50 includes spacers 51 and 52. The spacers 51 and 52 are provided at different positions on the surface F10. The spacers 51 and 52 are disposed side by side in the Y direction substantially perpendicular to both the Z and X directions. The Y direction is an example of a third direction. The spacers 51 and 52 have substantially rectangular shapes when viewed in the Z direction. The spacers 51 and 52 are provided at the positions of respective ends of a semiconductor chip 61.

The semiconductor chip 30 is provided on the surface F10 so as to be disposed between the spacers 51 and 52. The semiconductor chip 30 has a substantially rectangular shape when viewed in the Z direction. The thickness of the semiconductor chip 30 is substantially equal to the thicknesses of the spacers 51 and 52. The thickness of the semiconductor chip 30 is its thickness in the Z direction.

No spacers are provided beside the semiconductor chip 30 in the X direction. Thus, hollow regions R exists beside the semiconductor chip 30 in the X direction. Each hollow region R is a region between an end part of the semiconductor chip 30 and an end part of semiconductor chips 62 to 64.

The stacked body S is provided above the spacers 51 and 52 and the semiconductor chip 30. The stacked body S is a stacked body in which the semiconductor chips 60 are stacked in the Z direction substantially perpendicular to the surface F10. The Z direction is an example of the first direction. The semiconductor chips 60 are stacked with offsets in the X direction. More specifically, the stacked body S includes four semiconductor chips 60 continuously stacked with offsets in the X direction. An offset amount OA is an offset amount between two semiconductor chips 60 stacked adjacent to each other in the X direction.

The stacked body S is a stacked body in which the four semiconductor chips 61 to 64 are stacked in order from below. The semiconductor chip 62 provided on the lowermost semiconductor chip 61 is stacked with an offset relative to the lowermost semiconductor chip 61 in the X direction substantially parallel to the surface F10. The X direction is an example of the second direction.

As illustrated in FIGS. 1A, 1B, 1C, and 2, the lowermost semiconductor chip 61 is thicker than the three upper semiconductor chips 62 to 64. The three upper semiconductor chips 62 to 64 among the four semiconductor chips 61 to 64 continuously stacked with offsets in the X direction each have a thickness of, for example, 20 μm or larger and 100 μm or smaller. The thickness is more preferably 20 μm or larger and 60 μm or smaller. The thickness is further more preferably 20 μm or larger and 40 μm or smaller. The thicknesses of the semiconductor chips 60 are their thicknesses in the Z direction. The lowermost semiconductor chip 61 has a thickness of, for example, 40 μm or larger and 200 μm or smaller. The thickness is more preferably 40 μm or larger and 100 μm or smaller. The thickness is further more preferably 40 μm or larger and 60 μm or smaller.

In a case where the lowermost semiconductor chip 61 has a relatively small thickness of, for example, 200 μm or smaller, stress potentially becomes high at positions on the lowermost semiconductor chip 61, the positions corresponding to the vicinities of end parts of the semiconductor chip 30, when the semiconductor chips 62 to 64 are mounted (refer to triangles in the cross sectional view of FIG. 1B). Furthermore, the hollow regions R are larger for an upper semiconductor chip among the semiconductor chips 62 to 64 because of an offset, and accordingly, the stress on the semiconductor chip 61 at mounting is higher. As a result, the stress on the semiconductor chip 61 locally concentrates and potentially generates cracks.

If the lowermost semiconductor chip 61 is thickened, the stress on the semiconductor chip 61 at mounting of the semiconductor chips 62 to 64 is reduced and cracks can be prevented. However, if the lowermost semiconductor chip 61 is thickened too much, a package of the semiconductor device 1 becomes too thick. As a result, it becomes difficult to downsize the package.

Thus, the semiconductor chip 30 is misaligned (shifted) relative from the central position of the lowermost semiconductor chip 61 in the X direction when viewed in the Z direction. In other words, the central position of the semiconductor chip 30 is separated from the central position of the lowermost semiconductor chip 61 in a direction in which the semiconductor chip 62 is offset. The X direction as the direction in which the semiconductor chip 30 is shifted is the short side direction of the semiconductor chip 30. The stress at mounting of the semiconductor chips 62 to 64 can be reduced by scaling down the hollow regions R. Accordingly, it is possible to prevent increase in the thickness of the package as well as crack generation at a position where the stress is high. The center of a semiconductor chip may be a point where diagonal lines connecting its apexes intersect in a plan view or may be its barycenter in a plan view.

The stress applied on the semiconductor chip 61 at mounting of the semiconductor chip 61 potentially becomes high due to misalignment of the position of the semiconductor chip 30. However, in a case where the semiconductor chip 61 is thicker than the semiconductor chips 62 to 64, a load at mounting of the semiconductor chip 61 is smaller than a load at mounting of the semiconductor chips 62 to 64. Thus, the stress applied on the semiconductor chip 61 can be reduced even when the semiconductor chip 30 is misaligned relative to the central position of the lowermost semiconductor chip 61.

The stress at mounting of the semiconductor chip 64 will be described below.

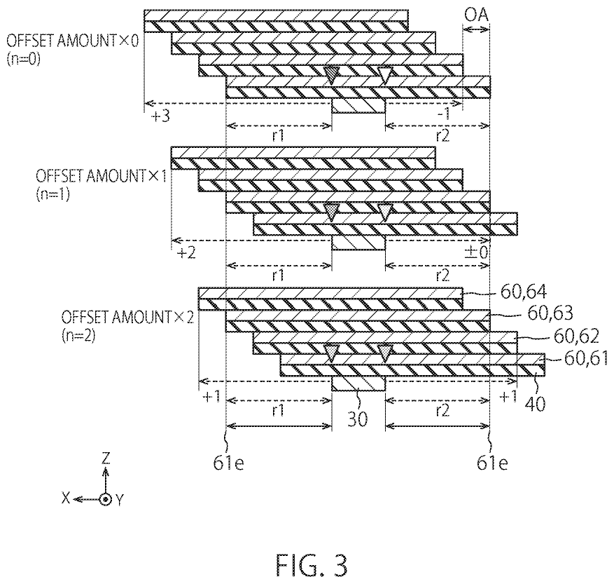

FIG. 3 is a cross sectional view illustrating an example of the relation between the position of the semiconductor chip 30 and the stress at mounting of the semiconductor chip 64 according to the first embodiment. FIG. 3 corresponds to the timing of mounting the uppermost semiconductor chip 64, at which the stress is highest.

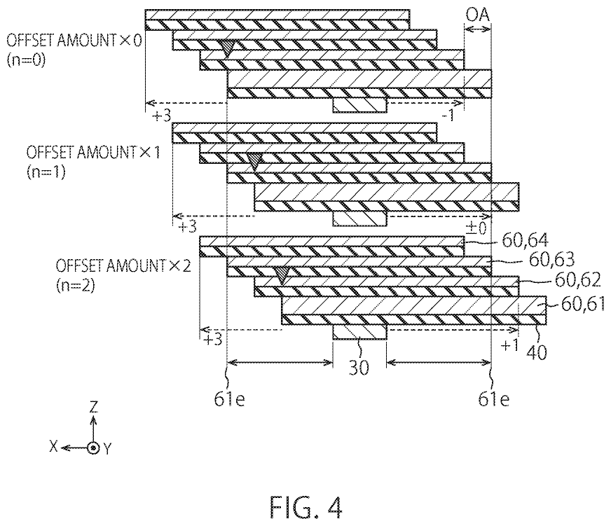

In schematic illustration of FIG. 4, the thickness of the lowermost semiconductor chip 61 is substantially equal to the thicknesses of the other semiconductor chips 62 to 64. However, the thickness of the lowermost semiconductor chip 61 may be different from the thicknesses of the other semiconductor chips 62 to 64 and is, for example, 200 μm or smaller. The three upper semiconductor chips 62 to 64 may be thinner than the lowermost semiconductor chip 61.

Each triangle illustrated in FIG. 3 represents stress at mounting of the uppermost semiconductor chip 64. The position of the triangle represents a position where the stress is high. The grayscale of the triangle represents the strength of the stress. The stress is higher as the color of the triangle is darker, and the stress is lower as the color of the triangle is lighter.

FIG. 3 illustrates the stress in a case where the semiconductor chip 30 is misaligned by the offset amount OA of the semiconductor chips 60×n (n=0, 1, 2) in the X direction. In FIG. 3, the position of the semiconductor chip 30 in the X direction is fixed and the semiconductor chips 61 to 64 are misaligned relative to the semiconductor chip 30.

In the case of n=0, the semiconductor chip 30 is disposed substantially at the central position of the lowermost semiconductor chip 61. The hollow amount (distance of each hollow region R) from the left end of the semiconductor chip 30 to the left end of the semiconductor chip 64 is an amount obtained by adding the triple of the offset amount OA to the distance (r1) to an end part 61e of the semiconductor chip 61 with n=0. The hollow amount is r1+3×OA, which is expressed as +3 in FIG. 3. The hollow amount (distance of each hollow region R) from the right end of the semiconductor chip 30 to the right end of the semiconductor chip 62 is an amount obtained by subtracting the offset amount OA from the distance (r2) to the end part 61e of the semiconductor chip 61 with n=0. The hollow amount is r2−1×OA, which is expressed as −1 in FIG. 3. Similar expressions are obtained in the cases of n=1 and n=2. In the present embodiment, r1 and r2 are equal to each other for n=0.

The stress on the semiconductor chip 61 at mounting of the semiconductor chip 64 is high at positions corresponding to the respective ends of the semiconductor chip 30. Since the hollow amount is large on the left side, the stress on the semiconductor chip 61 is high at a position corresponding to the left end of the semiconductor chip 30. Since the hollow amount is small on the right side, the stress on the semiconductor chip 61 is low at a position corresponding to the right end of the semiconductor chip 30.

In the case of n=1, unlike the case of n=0, the semiconductor chips 61 to 64 are misaligned relative to the semiconductor chip 30 in the negative X direction by the offset amount OA. The hollow amount (distance of each hollow region R) from the left end of the semiconductor chip 30 to the left end of the semiconductor chip 64 is an amount obtained by adding the double of the offset amount OA to the distance (r1) to the end part 61e of the semiconductor chip 61 with n=0 and is +2. The hollow amount (distance of each hollow region R) from the right end of the semiconductor chip 30 to the right end of the semiconductor chip 62 is equal to the distance (r2) to the end part 61e of the semiconductor chip 61 with n=0 and is 0.

The stress on the semiconductor chip 61 at mounting of the semiconductor chip 64 is high at positions corresponding to the respective ends of the semiconductor chip 30. Since the hollow amount on the left side is smaller than in the case of n=0, the stress on the semiconductor chip 61 is lower than in the case of n=0. Since the hollow amount on the right side is larger than in the case of n=0, the stress on the semiconductor chip 61 is higher than in the case of n=0.

In the case of n=2, unlike the case of n=1, the semiconductor chips 61 to 64 are misaligned relative to the semiconductor chip 30 in the negative X direction by the offset amount OA. The hollow amount (distance of each hollow region R) from the left end of the semiconductor chip 30 to the left end of the semiconductor chip 64 is an amount obtained by adding the offset amount OA to the distance (r1) to the end part 61e of the semiconductor chip 61 with n=0 and is +1. The hollow amount (distance of each hollow region R) from the right end of the semiconductor chip 30 to the right end of the semiconductor chip 62 is an amount obtained by adding the offset amount OA to the distance (r2) to the end part 61e of the semiconductor chip 61 with n=0 and is +1.

The stress on the semiconductor chip 61 at mounting of the semiconductor chip 64 is high at positions corresponding to the respective ends of the semiconductor chip 30. Since the hollow amount on the left side is smaller than in the case of n=1, the stress on the semiconductor chip 61 is lower than in the case of n=1. Since the hollow amount on the right side is larger than in the case of n=1, the stress on the semiconductor chip 61 is higher than in the case of n=1.

In the example with n=2, the hollow amount is balanced between the left and right sides of the semiconductor chip 30 and the stress is equivalent therebetween. Thus, the stress at mounting of the semiconductor chip 64 can be reduced by misaligning the semiconductor chip 30 relative to the lowermost semiconductor chip 61 in the offset direction (X direction) of the semiconductor chips 60.

In the example illustrated in FIG. 3, wire bonding is performed at the end parts of the semiconductor chips 60 on the right side. Stress due to wire bonding is applied on the semiconductor chips 60, and thus the semiconductor chip 30 may be disposed such that the hollow amount on the right side is lower than the hollow amount on the left side. Thus, the shift amount of the semiconductor chip 30 may be adjusted, for example, as in the example with n=1 with taken into account both the stress at mounting and the stress at wire bonding.

Specifically, the semiconductor chip 30 is misaligned relative to the central position of the lowermost semiconductor chip 61 in the X direction by ½ or more of the offset amount OA of the semiconductor chip 62 on the lowermost semiconductor chip 61. In other words, the central position of the semiconductor chip 30 is separated from the central position of the lowermost semiconductor chip 61 in the X direction by ½ or more of the offset amount OA. The semiconductor chip 30 is more preferably misaligned relative to the offset amount OA of the semiconductor chip 62 approximately. The offset amount OA of the semiconductor chip 62 is, for example, the offset amount OA between the lowermost semiconductor chip 61 and the semiconductor chip 62. The offset amounts OA of the semiconductor chips 62 to 64 are, for example, 200 μm to 300 μm. A mount device has a mounting accuracy of, for example, ±30 μm.

As described above, according to the first embodiment, the semiconductor chip 62 provided on the lowermost semiconductor chip 61 is stacked with an offset relative to the lowermost semiconductor chip 61 in the X direction substantially parallel to the surface F10. The semiconductor chip 30 is misaligned relative to the central position of the lowermost semiconductor chip 60 in the X direction when viewed in the Z direction.

The offset amount OA may be different for each semiconductor chip 60. Specifically, the offset amount OA between each two semiconductor chips 60 stacked adjacent to each other in the X direction may be different for each semiconductor chip 60. The offset amount OA of each semiconductor chip 60 is changed, for example, in accordance with the thickness of the semiconductor chip 60.

### First Comparative Example

FIG. 4 is a cross sectional view illustrating an example of the relation between the position of the semiconductor chip 30 and the stress at mounting of the semiconductor chip 64 according to a first comparative example. The first comparative example is different from the first embodiment in that the lowermost semiconductor chip 61 is thick. FIG. 4 corresponds to the timing of mounting the uppermost semiconductor chip 64, at which the stress is highest.

The thickness of each semiconductor chip 60 according to the first comparative example is a thickness with which the stress is highest not on the lowermost semiconductor chip 61. The thickness of the lowermost semiconductor chip 60 is, for example, larger than 200 μm.

As described above, local stress concentration on the semiconductor chip 61 is reduced by thickening the lowermost semiconductor chip 61. As illustrated in FIG. 4, in a case where the lowermost semiconductor chip 61 is thick, stress is high at a position on the semiconductor chip 62, the position corresponding to the vicinity of an end part of the semiconductor chip 61. The magnitude of stress is determined by the distance from the end part of the lowermost semiconductor chip 61 to the corresponding end part of the uppermost semiconductor chip 64. As illustrated in FIG. 4, the position where stress is high and the magnitude of stress substantially do not change with the position of the semiconductor chip 30. Furthermore, as described above, if the lowermost semiconductor chip 61 is thickened too much, the package of the semiconductor device 1 becomes too thick.

However, in the first embodiment, the lowermost semiconductor chip 61 is relatively thin and the semiconductor chip 30 is misaligned in the offset direction of the semiconductor chips 60 as illustrated in FIG. 3. Accordingly, it is possible to prevent increase in the thickness of the package of the semiconductor device 1 as well as crack generation at a position where stress is high.

### Second Comparative Example

Spacers are provided beside the semiconductor chip 30 in the X direction in some cases to scale down the hollow regions R. However, in such a case, assembly cost increases and the number of processes increases.

However, in the first embodiment, no spacers are provided beside the semiconductor chip 30 in the X direction and the semiconductor chip 30 is misaligned in the offset direction of the semiconductor chips 60 as illustrated in FIGS. 1A and 1B. Accordingly, it is possible to prevent increase in the number of spacers as well as crack generation at a position where stress is high.

### Second Embodiment

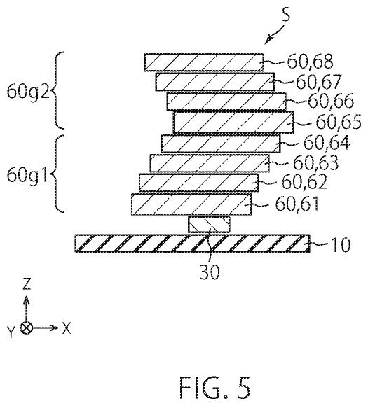

FIG. 5 is a cross sectional view illustrating an example of the configuration of the semiconductor device 1 according to a second embodiment. The second embodiment is different from the first embodiment in that additional semiconductor chips 60 (a plurality of semiconductor chips 65 to 68) are provided on the semiconductor chip 64.

The stacked body S includes at least one chip group 60g1 and at least one chip group 60g2.

The chip group 60g1 includes the four semiconductor chips 61 to 64 continuously stacked with offsets in the X direction.

The chip group 60g2 includes the four semiconductor chips 65 to 68 continuously stacked with offsets in a direction (the negative X direction) opposite the X direction.

The semiconductor chip 65 has the same thickness as the semiconductor chip 61. The semiconductor chips 66 to 68 have the same thicknesses as the semiconductor chips 62 to 64. With the above-described thickness relation, a load at mounting of the semiconductor chip 65 is lower than a load at mounting of the semiconductor chip 64. Thus, even in a case where the semiconductor chip 65 is offset relative to the semiconductor chip 64 in the X direction, the risk of stress and crack on the semiconductor chip 61 at mounting of the semiconductor chip 65 is lower than at mounting of the semiconductor chip 64.

The chip groups 60g1 and 60g2 are alternately stacked. Specifically, the semiconductor chips 60 are stacked with a return at every four tiers.

In the example illustrated in FIG. 5, the stacked body S includes one chip group 60g1 and one chip group 60g2. However, the number of chip groups 60g1 and 60g2 is not limited thereto. For example, in a case where the stacked body S includes two chip groups 60g1 and two chip groups 60g2, the stacked body S includes semiconductor chips 60 stacked in 16 tiers.

As in the second embodiment, additional semiconductor chips 60 may be provided on the semiconductor chip 64. The semiconductor device 1 according to the second embodiment can obtain the same effects as in the first embodiment.

### Third Embodiment

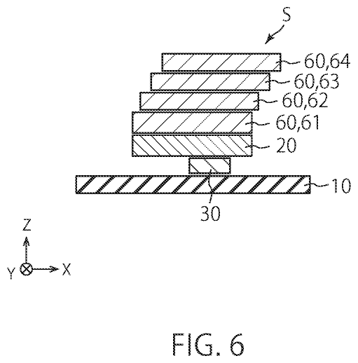

FIG. 6 is a cross sectional view illustrating an example of the configuration of the semiconductor device 1 according to a third embodiment. The third embodiment is different from the first embodiment in that a dummy chip 20 is provided between the semiconductor chip 30 and the stacked body S.

The semiconductor device 1 additionally includes the dummy chip 20. The dummy chip 20 is provided on the spacers 51 and 52 and the semiconductor chip 30. The dummy chip 20 may include, for example, a wiring layer. In this case, the dummy chip 20 functions as a relay chip.

The stacked body S is provided on the dummy chip 20.

As in the third embodiment, the dummy chip 20 may be provided between the semiconductor chip 30 and the stacked body S. The semiconductor device 1 according to the third embodiment can obtain the same effects as in the first embodiment.

### Fourth Embodiment

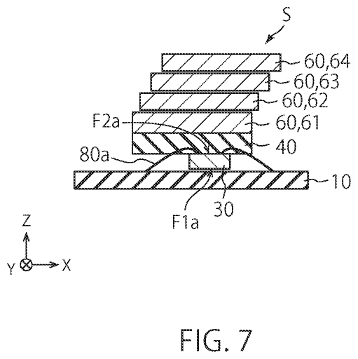

FIG. 7 is a cross sectional view illustrating an example of the configuration of the semiconductor device 1 according to a fourth embodiment. In the fourth embodiment, the semiconductor chip 30 is connected to the wiring substrate 10 through a bonding wire 80a in place of flip-chip connection.

The semiconductor chip 30 has a surface Fla facing the wiring substrate 10, and a surface F2a opposite the surface Fla. The surface F2a is provided with a plurality of metal pads.

The semiconductor device 1 additionally includes the bonding wire 80a. The bonding wire 80a electrically connects each metal pad of the semiconductor chip 30 to a metal pad of the wiring substrate 10.

The thickness of the semiconductor chip 30 is substantially equal to the thicknesses of the spacers 51 and 52.

In the fourth embodiment, the resin layer 40 provided on the lower surface of the lowermost semiconductor chip 61 may be thick unlike the first embodiment.

As in the fourth embodiment, the semiconductor chip 30 may be connected to the wiring substrate 10 through the bonding wire 80a. The semiconductor device 1 according to the fourth embodiment can obtain the same effects as in the first embodiment.

### Fifth Embodiment

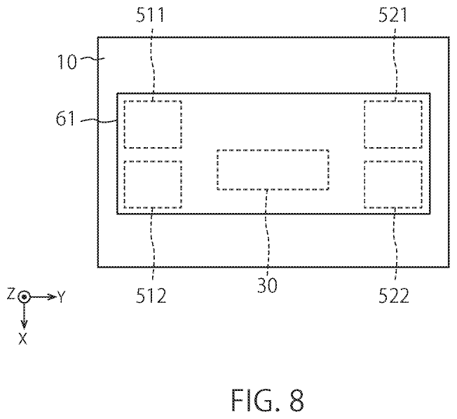

FIG. 8 is a plan view illustrating an example of the configuration of the semiconductor device 1 according to a fifth embodiment. The fifth embodiment is different from the first embodiment in the configurations of the spacers 51 and 52.

The spacer 51 includes spacers 511 and 512. The spacer 52 includes spacers 521 and 522. In the example illustrated in FIG. 8, the spacers 511, 512, 521, and 522 are disposed at four corners of the lowermost semiconductor chip 61, respectively. In this case as well, the semiconductor chip 30 is disposed between the spacers 51 and 52.

As in the fifth embodiment, the configurations of the spacers 51 and 52 may be changed. The semiconductor device 1 according to the fifth embodiment can obtain the same effects as in the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a substrate having a first surface;
a first spacer and a second spacer that are provided at different positions on the first surface;
a first semiconductor chip provided on the first surface so as to be disposed between the first spacer and the second spacer; and
a stacked body that is provided above the first spacer, the second spacer, and the first semiconductor chip and in which a plurality of second semiconductor chips are stacked in a first direction substantially perpendicular to the first surface, wherein
one of the second semiconductor chips, which is provided on the lowermost second semiconductor chip, is stacked with an offset relative to the lowermost second semiconductor chip in a second direction substantially parallel to the first surface, and
a central position of the first semiconductor chip is separated from a central position of the lowermost second semiconductor chip in the second direction when viewed in the first direction.

2. The semiconductor device according to claim 1, wherein the central position of the first semiconductor chip is separated from the central position of the lowermost second semiconductor chip in the second direction by ½ or more of an offset amount of the second semiconductor chip on the lowermost second semiconductor chip.

3. The semiconductor device according to claim 1, wherein an offset amount between each two of the second semiconductor chips in the second direction is different for each of the second semiconductor chips, the two second semiconductor chips being stacked adjacent to each other.

4. The semiconductor device according to claim 1, wherein the stacked body includes four of the second semiconductor chips, the four second semiconductor chips being continuously stacked with offsets in the second direction.

5. The semiconductor device according to claim 4, wherein
the stacked body includes
at least one first chip group including four of the second semiconductor chips, the four second semiconductor chips being continuously stacked with offsets in the second direction, and
at least one second chip group including four of the second semiconductor chips, the second semiconductor chips being continuously stacked with offsets in a direction opposite the second direction, and
the first and second chip groups are alternately stacked.

6. The semiconductor device according to claim 4, wherein the three upper second semiconductor chips among the four second semiconductor chips continuously stacked with offsets in the second direction each have a thickness of 20 μm or larger and 100 μm or smaller.

7. The semiconductor device according to claim 1, wherein the lowermost second semiconductor chip has a thickness of 40 μm or larger and 200 μm or smaller.

8. The semiconductor device according to claim 1, wherein
the first semiconductor chip has a substantially rectangular shape when viewed in the first direction, and
the second direction is a short side direction of the first semiconductor chip.

9. The semiconductor device according to claim 1, wherein the first spacer and the second spacer are disposed side by side in a third direction substantially perpendicular to both the first direction and the second direction.

10. The semiconductor device according to claim 1, wherein no spacers are provided beside the first semiconductor chip in the second direction.

11. The semiconductor device according to claim 1, further comprising a dummy chip provided on the first spacer, the second spacer, and the first semiconductor chip, wherein
the stacked body is provided on the dummy chip.
